(19) United States
(12) Patent Application Publication
(10) Pub. No.: US 2026/0143996 A1
(43) Pub. Date: May 21, 2026

(54) PROCESSING METHOD, PROCESSING DEVICE, AND WAFER MANUFACTURING METHOD

(71) Applicant: DISCO CORPORATION, Tokyo (JP)

(72) Inventor: Maho HIRAKAWA, Tokyo (JP)

(21) Appl. No.: 19/377,776

(22) Filed: Nov. 3, 2025

(30) Foreign Application Priority Data
Nov. 8, 2024 (JP) 2024-195699

(51) Int. Cl. H10P 72/00; B23K 26/53; B23K 101/40; B24B 7/22; H10P 72/50

(52) U.S. Cl. CPC H10P 72/0428; B23K 26/53; B24B 7/228; H10P 72/53; B23K 2101/40

(57) ABSTRACT

A method includes: holding a first workpiece on a first holding portion and holding a second workpiece on a second holding portion; and relatively moving the first workpiece and the second workpiece in an in-plane direction of a contact surface of the first workpiece and a contact surface of the second workpiece in a state in which the first workpiece and the second workpiece are in contact with each other to reduce unevenness of at least one of the contact surface of the first workpiece and the contact surface of the second workpiece. In the moving, the first workpiece and the second workpiece are brought into contact with each other such that an extending direction of the unevenness present on the contact surface of the first workpiece and an extending direction of the unevenness present on the contact surface of the second workpiece intersect each other.

### CROSS-REFERENCE TO RELATED APPLICATIONS

This application is based on and claims priority under 35 USC 119 from Japanese Patent Application No. 2024-195699 filed on Nov. 8, 2024, the contents of which are incorporated herein by reference.

### TECHNICAL FIELD

The present disclosure relates to a processing method, a processing device, and a wafer manufacturing method.

### BACKGROUND

A wafer made of a material such as silicon (Si) or the like is used for manufacturing an electronic device such as an integrated circuit (IC) or a large scale integration (LSI). A wafer made of a material which is a hexagonal single crystal such as silicon carbide (SiC) or gallium nitride (GaN) is used for manufacturing a power device or an optical device such as a light emitting diode (LED) or a laser diode (LD).

In a wafer producing method described in JP2016-111143A, a focal point of a laser beam having a wavelength transmittable through an ingot made of a material is positioned inside the ingot and the ingot is irradiated with the laser beam to form a release layer on a planned cutting surface of the ingot. The wafer is released from the ingot along the release layer.

The release surface of the wafer released from the ingot and the release surface of the ingot from which the wafer is released have unevenness, and these release surfaces are typically processed to be flat by a grinding wheel or a polishing pad.

In a processing method described in JP2023-116242A, the release surfaces of the ingot and the wafer are rubbed against each other to process the release surfaces to be flat.

The processing method described in JP2023-116242A can reduce wear of a tool such as a grinding wheel and reduce the processing cost. However, if the unevenness of the release surfaces meshes with each other when the release surfaces of the ingot and the wafer are rubbed against each other, damage such as cracking or chipping may occur in the wafer.

The present disclosure provides a processing method, a processing device, and a wafer manufacturing method capable of reducing damage to a workpiece such as a wafer and reducing unevenness of a surface of the workpiece.

### SUMMARY

A first aspect of the present disclosure relates to a processing method for a workpiece. The processing method includes: holding a first workpiece on a first holding portion and holding a second workpiece made of the same material as the first workpiece on a second holding portion; and relatively moving the first workpiece and the second workpiece in an in-plane direction of a contact surface of the first workpiece and a contact surface of the second workpiece in a state in which the first workpiece and the second workpiece are in contact with each other to reduce unevenness of at least one of the contact surface of the first workpiece and the contact surface of the second workpiece. In the moving, the first workpiece and the second workpiece are brought into contact with each other such that an extending direction of the unevenness present on the contact surface of the first workpiece and an extending direction of the unevenness present on the contact surface of the second workpiece intersect each other.

A second aspect of the present disclosure relates to a processing device including: a first holding portion configured to hold a first workpiece; a second holding portion configured to hold a second workpiece made of the same material as the first workpiece held by the first holding portion so as to face the first workpiece held by the first holding portion; and a moving mechanism configured to relatively move the first holding portion and the second holding portion in an in-plane direction of a contact surface of the first workpiece and a contact surface of the second workpiece in a state in which the first workpiece held by the first holding portion and the second workpiece held by the second holding portion are in contact with each other. The moving mechanism relatively moves the first holding portion and the second holding portion so as to maintain a state in which a first direction defined in the contact surface of the first workpiece held by the first holding portion and a second direction defined in the contact surface of the second workpiece held by the second holding portion intersect each other.

A third aspect of the present disclosure relates to a wafer manufacturing method for manufacturing a wafer having a thickness less than a thickness of an ingot from the ingot. The wafer manufacturing method includes: forming a release layer inside the ingot by positioning a focal point of a laser beam having a wavelength that is transmittable through the ingot inside the ingot and scanning the ingot with the laser beam; releasing the wafer from the ingot with the release layer as a starting point; and reducing unevenness of a release surface of the wafer. In the reducing, the wafer and the ingot or the other wafer are moved relative to each other in a state in which the release surface of the wafer is in contact with a release surface of the ingot or a release surface of the other wafer to which the reducing is not performed to reduce the unevenness of the release surface of the wafer, and in the reducing, a state is maintained in which a first direction in the release surface of the wafer corresponding to a scanning direction of the laser beam and a second direction in the release surface of the ingot corresponding to the scanning direction of the laser beam or a second direction in the release surface of the other wafer corresponding to the scanning direction of the laser beam intersect each other, and the wafer and the ingot or the other wafer are moved relative to each other.

### BRIEF DESCRIPTION OF DRAWINGS

Exemplary embodiment(s) of the present disclosure will be described in detail based on the following figures, wherein

FIG. 1 schematically shows an example of a processing device according to Embodiment 1;

FIG. 2 is a plan view schematically showing an example of a workpiece to be processed by a processing method according to Embodiment 1;

FIG. 3 is a flowchart showing a flow of the processing method according to Embodiment 1;

FIG. 4 shows an example of a captured image of a contact surface of the workpiece acquired in an angle adjustment step in FIG. 3;

FIG. 5 is a side view schematically showing the state of the workpiece immediately after the start of an unevenness reducing step in FIG. 3;

FIG. 6 is a side view schematically showing the state of the workpiece immediately before the unevenness reducing step in FIG. 3 is completed;

FIG. 7 is a plan view schematically showing the arrangement of a first workpiece and a second workpiece in the unevenness reducing step in FIG. 3 in relation to the extending direction of the unevenness present on the contact surface;

FIG. 8 is a perspective view schematically showing a state in which the first workpiece is ground in a grinding step in FIG. 3;

FIG. 9 is a perspective view showing a state in which the second workpiece is ground in the grinding step in FIG. 3;

FIG. 10 is a flowchart showing a flow of a modification of the processing method in FIG. 3;

FIG. 11 is a perspective view schematically showing an angle adjustment step in FIG. 10;

FIG. 12 is a perspective view schematically showing Modification 1 of the relative movement between the first workpiece and the second workpiece in the processing method according to Embodiment 1;

FIG. 13 is a plan view schematically showing Modification 1 of the relative movement between the first workpiece and the second workpiece in the processing method according to Embodiment 1;

FIG. 14 is a view schematically showing an example of a processing device that achieves the relative movement between the first workpiece and the second workpiece shown in FIGS. 12 and 13;

FIG. 15 is a perspective view schematically showing Modification 2 of the relative movement between the first workpiece and the second workpiece in the processing method according to Embodiment 1;

FIG. 16 is a plan view schematically showing Modification 2 of the relative movement between the first workpiece and the second workpiece in the processing method according to Embodiment 1;

FIG. 17 is a view schematically showing an example of a processing device that achieves the relative movement between the first workpiece and the second workpiece shown in FIGS. 15 and 16;

FIG. 18 is a plan view of an ingot used in a processing method and a wafer manufacturing method according to Embodiment 2;

FIG. 19 is a side view of the ingot shown in FIG. 18;

FIG. 20 is a perspective view of a wafer produced by the processing method and the wafer manufacturing method according to Embodiment 2;

FIG. 21 is a flowchart showing a flow of the processing method and the wafer manufacturing method according to Embodiment 2;

FIG. 22 is a perspective view schematically showing a release layer forming step in FIG. 21;

FIG. 23 is a side view schematically showing the release layer forming step in FIG. 21;

FIG. 24 is a perspective view schematically showing a wafer producing step in FIG. 21;

FIG. 25 is a side view schematically showing an unevenness reducing step in FIG. 21;

FIG. 26 is a side view schematically showing Modification 1 of the processing method according to Embodiment 2; and

FIG. 27 is a side view schematically showing Modification 2 of the processing method according to Embodiment 2.

### DESCRIPTION OF EMBODIMENTS

Embodiments of the present disclosure will be described in detail with reference to the drawings.

The present disclosure is not limited by the contents described in the following embodiments. The components to be described below include those that can be easily conceived by those skilled in the art and those that are substantially the same. Further, the configurations to be described below can be appropriately combined. Various omissions, substitutions, or changes of the configurations can be made without departing from the gist of the present disclosure.

### Embodiment 1

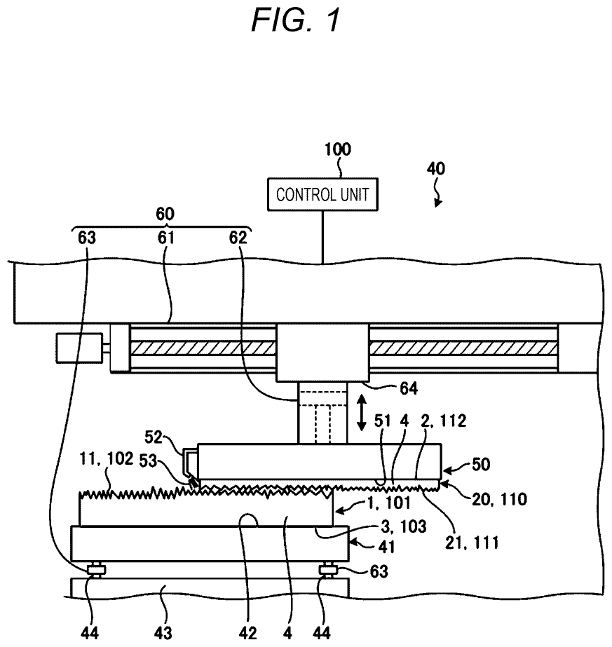

A processing device and a processing method according to Embodiment 1 of the present disclosure will be described with reference to the drawings. FIG. 1 schematically shows the processing device according to Embodiment 1. A processing device 40 is a device that reduces at least one of the unevenness present on a contact surface 102, which is one surface of a first workpiece 101, and the unevenness present on a contact surface 111, which is one surface of a second workpiece 110. The first workpiece 101 and the second workpiece 110 are made of the same material. The processing device 40 includes a first holding portion 41, a second holding portion 50, a moving mechanism 60, and a control unit 100.

The first holding portion 41 holds a back surface 103 of the first workpiece 101 opposite to the contact surface 102 on a holding surface 42 parallel to the horizontal direction. The holding surface 42 of the first holding portion 41 is connected to a vacuum suction source (not shown), and the holding surface 42 is suctioned by the vacuum suction source, whereby the first holding portion 41 suctions and holds the back surface 103 of the first workpiece 101 placed on the holding surface 42.

The second holding portion 50 holds the second workpiece 110 so as to face the contact surface 102 of the first workpiece 101 held by the first holding portion 41. The second holding portion 50 is formed in a disk shape and has a holding surface 51 that holds the second workpiece 110 such that the contact surface 111 of the second workpiece 110 faces the contact surface 102 of the first workpiece 101 held by the first holding portion 41. The holding surface 51 is flat along the horizontal direction. The holding surface 51 of the second holding portion 50 is connected to a vacuum suction source (not shown), and the holding surface 51 is suctioned by the vacuum suction source, whereby the second holding portion 50 suctions and holds the back surface 112 of the second workpiece 110 opposite to the contact surface 111 on the holding surface 51. The second holding portion 50 is moved by the moving mechanism 60 in a state in which the second workpiece 110 is suctioned and held on the holding surface 51.

A liquid supply nozzle 52 is attached to the second holding portion 50. The liquid supply nozzle 52 supplies a liquid 53 (for example, pure water) between the first workpiece 101 held by the first holding portion 41 and the second workpiece 110 held by the second holding portion 50.

The moving mechanism 60 relatively moves the first holding portion 41 and the second holding portion 50, and may include a guide rail. The moving mechanism 60 includes a first moving unit 61, a second moving unit 62, and a pressure sensor 63.

The first moving unit 61 relatively moves the first holding portion 41 and the second holding portion 50 in a direction (the horizontal direction in Embodiment 1) parallel to the contact surfaces 102 and 111. The first moving unit 61 is provided above the first holding portion 41. In Embodiment 1, the first moving unit 61 moves a moving table 64 holding the second moving unit 62 in the horizontal direction. The first moving unit 61 moves the moving table 64 in the horizontal direction to move the second holding portion 50 together with the second moving unit 62 in the horizontal direction between a position where the holding surface 51 of the second holding portion 50 faces the holding surface 42 of the first holding portion 41 along the vertical direction and a retracted position where the holding surface 51 is retracted from the holding surface 42 of the first holding portion 41.

The second moving unit 62 moves the first holding portion 41 and the second holding portion 50 relatively away from or close to each other in a direction (the vertical direction in Embodiment 1) intersecting the contact surfaces 102 and 111. The second moving unit 62 is provided on the moving table 64, and in Embodiment 1, by moving the second holding portion 50 in the vertical direction, the first holding portion 41 and the second holding portion 50 are relatively released or brought close to each other in the direction intersecting the contact surfaces 102 and 111.

Each of the first moving unit 61 and the second moving unit 62 includes a known ball screw that is rotatable about an axis and rotates about the axis to move the moving table 64 in the horizontal direction or the second holding portion 50 in the vertical direction, a known motor that rotates the ball screw about the axis, and a known guide rail that supports the moving table 64 or the second holding portion 50 such that the moving table 64 is movable in the horizontal direction or the second holding portion 50 is movable in the vertical direction.

The pressure sensor 63 is provided in at least one of the first holding portion 41 and the second holding portion 50, and measures a pressure generated by pressing the first workpiece 101 held by the first holding portion 41 against the second workpiece 110 held by the second holding portion 50. The pressure sensor 63 includes, for example, a known strain gauge, measures information corresponding to the pressure, and outputs a measurement result to the control unit 100.

In Embodiment 1, the pressure sensors 63 are provided between an installation base 43 on which the first holding portion 41 is provided and the first holding portion 41, and are provided on pillars 44 that support the first holding portion 41, for a total of three pressure sensors. The position at which the pressure sensor 63 is provided is not limited to the position between the installation base 43 and the first holding portion 41 as long as the information corresponding to the pressure generated by pressing the first workpiece 101 held by the first holding portion 41 against the second workpiece 110 held by the second holding portion 50 can be measured. The pressure sensor 63 may be provided between the second moving unit 62 and the second holding portion 50, in the second holding portion 50, or in the first holding portion 41.

The control unit 100 controls the components of the processing device 40 to cause the processing device 40 to perform an operation of reducing the unevenness of the contact surfaces 102 and 111. The control unit 100 is a computer including an arithmetic processing device including a microprocessor such as a central processing unit (CPU), a storage device including a memory such as a read only memory (ROM) or a random access memory (RAM), and an input/output interface device. The arithmetic processing device of the control unit 100 executes arithmetic processing according to a computer program stored in the storage device, and outputs a control signal for controlling the processing device 40 to the components of the processing device 40 via the input/output interface device.

The control unit 100 is connected to a display unit including a liquid crystal display device or the like that displays a state of a processing operation, an image, or the like, and an input unit used when an operator registers processing content information or the like. The input unit includes a touch panel provided on the display unit.

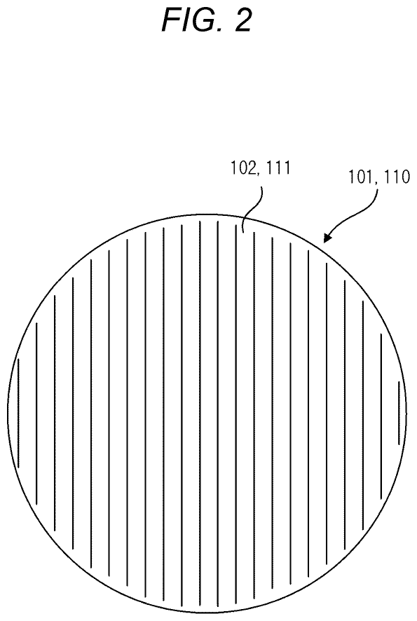

FIG. 2 is a plan view schematically showing the contact surface 102 of the workpiece 101 and the contact surface 111 of the workpiece 110. The first workpiece 101 is a disk-shaped or columnar workpiece. The contact surface 102, which is one surface of the first workpiece 101, has unevenness extending linearly in one direction in the plane of the contact surface 102. In FIG. 2, the unevenness of the contact surface 102 is schematically indicated by a large number of solid lines parallel to each other. The second workpiece 110 is also a disk-shaped or columnar workpiece, and the contact surface 111, which is one surface of the second workpiece 110, has unevenness extending linearly in one direction in the plane of the contact surface 111.

### Processing Method

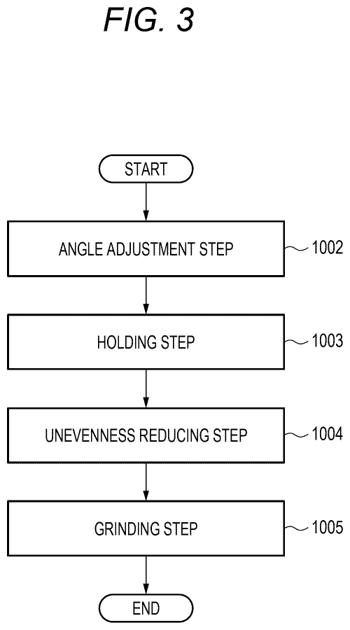

FIG. 3 is a flowchart showing a flow of the processing method according to Embodiment 1. The processing method according to Embodiment 1 is a method of bringing the first workpiece 101 and the second workpiece 110 into contact with each other such that the extending direction of the unevenness present on the contact surface 102 of the first workpiece 101 and the extending direction of the unevenness present on the contact surface 111 of the second workpiece 110 intersect each other, and reducing at least one of the unevenness of the contact surface 102 of the first workpiece 101 and the unevenness of the contact surface 111 of the second workpiece 110. As shown in FIG. 3, the processing method according to Embodiment 1 includes an angle adjustment step 1002, a holding step 1003, an unevenness reducing step 1004, and a grinding step 1005.

### Angle Adjustment Step

In the angle adjustment step 1002, the posture angle of the first workpiece 101 when the first workpiece 101 is placed on the first holding portion 41 and the posture angle of the second workpiece 110 when the second workpiece 110 is placed on the second holding portion 50 are set such that the extending direction of the unevenness present on the contact surface 102 of the first workpiece 101 and the extending direction of the unevenness present on the contact surface 111 of the second workpiece 110 intersect each other.

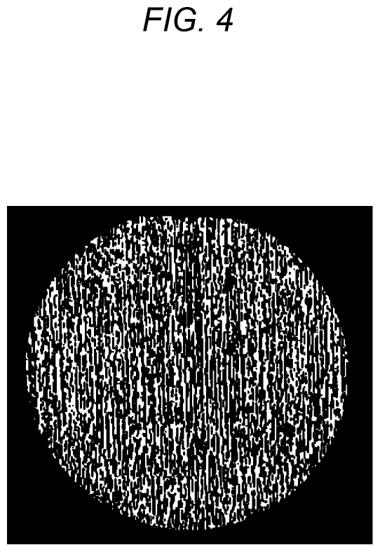

The extending directions of the unevenness of the contact surfaces 102 and 111 are detected based on a captured image of the contact surfaces 102 and 111 acquired by irradiating the contact surfaces 102 and 111 with light and detecting reflected light reflected by the contact surfaces 102 and 111. FIG. 4 shows an example of a captured image, and a striped pattern in which bright lines and dark lines extending in one direction are repeated in a direction orthogonal to the one direction appears in the captured image. The extending direction of the bright lines and the dark lines in the striped pattern corresponds to the extending direction of the unevenness. Such a captured image can be acquired using, for example, a white light interferometer widely used for measurement of surface roughness or the like.

The intersection angle between the extending direction of the unevenness of the contact surface 102 and the extending direction of the unevenness of the contact surface 111 is, for example, 90°, but is not limited to 90°. At least one of the first workpiece 101 and the second workpiece 110 is rotated such that the intersection angle between the extending direction of the unevenness of the contact surface 102 and the extending direction of the unevenness of the contact surface 111 becomes a predetermined angle. Then, the first workpiece 101 and the second workpiece 110 are conveyed to the first holding portion 41 and the second holding portion 50 by an appropriate conveying device such as a robot arm while maintaining the set intersection angle.

### Holding Step

The holding step 1003 is a step of holding the first workpiece 101 on the first holding portion 41 and holding the second workpiece 110 on the second holding portion 50. In the holding step 1003, the control unit 100 of the processing device 40 controls the moving mechanism 60 to position the second holding portion 50 at the retracted position and to raise the second holding portion 50. In the holding step 1003, the control unit 100 of the processing device 40 controls the first holding portion 41 and the second holding portion 50 to suction and hold the back surface 103 of the first workpiece 101 on the holding surface 42 of the first holding portion 41 and to suction and hold the back surface 112 of the second workpiece 110 on the holding surface 51 of the second holding portion 50.

### Unevenness Reducing Step

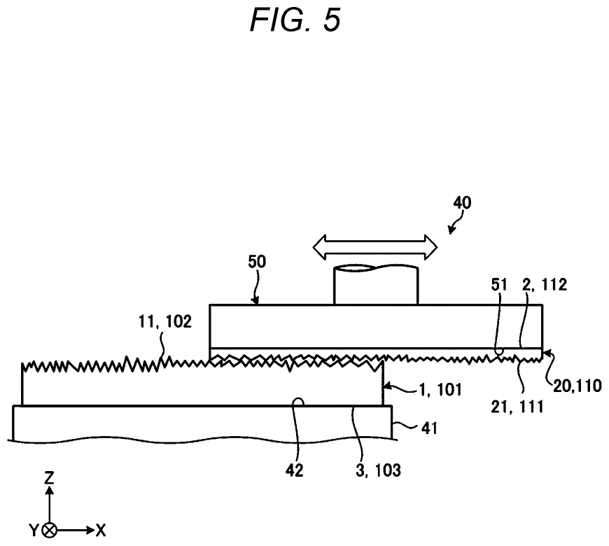

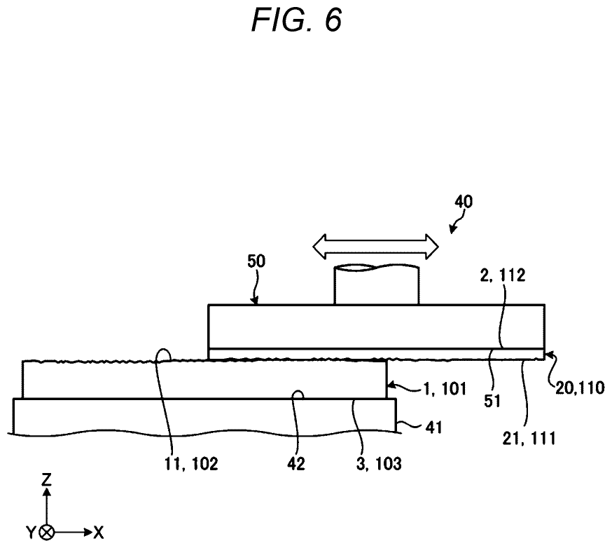

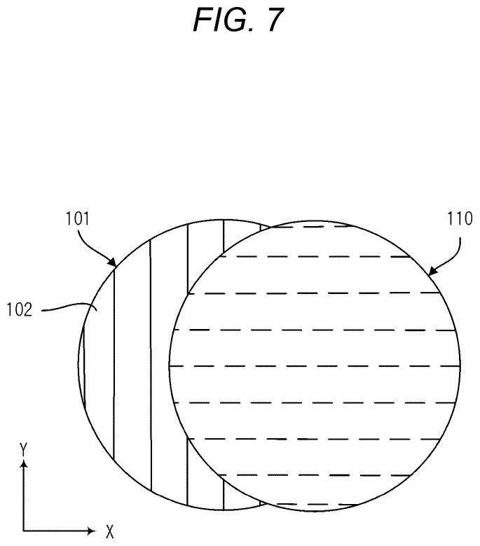

FIG. 5 is a side view schematically showing a state immediately after the start of the unevenness reducing step in FIG. 3. FIG. 6 is a side view schematically showing a state immediately before the unevenness reducing step in FIG. 3 is completed. FIG. 7 is a plan view schematically showing the arrangement of the first workpiece 101 and the second workpiece 110 in the unevenness reducing step 1004 in FIG. 3 in relation to the extending directions of the unevenness present on the contact surfaces 102 and 111. The unevenness reducing step 1004 is a step of reducing the unevenness of the contact surface 102 or 111 of at least one of the first workpiece 101 and the second workpiece 110 by relatively moving the first holding portion 41 and the second holding portion 50 in a state in which the contact surface 102 of the first workpiece 101 and the contact surface 111 of the second workpiece 110 are in contact with each other. In Embodiment 1, in the unevenness reducing step 1004, both the unevenness of the contact surface 102 of the first workpiece 101 and the unevenness of the contact surface 111 of the second workpiece 110 are reduced.

In the unevenness reducing step 1004, as shown in FIG. 5, the control unit 100 of the processing device 40 controls the first moving unit 61 and the second moving unit 62 to bring the contact surface 111 of the second workpiece 110 held by the second holding portion 50 into contact with the contact surface 102 of the first workpiece 101 held by the first holding portion 41. As shown in FIG. 7, the first workpiece 101 is provided such that the extending direction of the unevenness present on the contact surface 102 coincides with the Y direction, which is one direction of the horizontal directions. The second workpiece 110 is provided such that the extending direction of the unevenness present on the contact surface 111 coincides with the X direction, which is one direction of the horizontal directions. The contact surfaces 102 and 111 come into contact with each other in a state in which the extending direction of the unevenness of the contact surface 102 and the extending direction of the unevenness of the contact surface 111 intersect at an angle of 90°.

In the unevenness reducing step 1004, as shown in FIG. 5, the control unit 100 of the processing device 40 controls the first moving unit 61 to relatively move the first workpiece 101 and the second workpiece 110 for a predetermined time while supplying the liquid 53 from the liquid supply nozzle 52 (omitted in FIG. 5) in a state in which the contact surface 102 of the first workpiece 101 and the contact surface 111 of the second workpiece 110 are in contact with each other. In Embodiment 1, in the unevenness reducing step 1004, the control unit 100 of the processing device 40 controls the first moving unit 61 to reciprocate the second workpiece 110 relative to the first workpiece 101 in the horizontal direction.

In Embodiment 1, in the unevenness reducing step 1004, the control unit 100 of the processing device 40 adjusts the distance between the first holding portion 41 and the second holding portion 50 by controlling the second moving unit 62 such that the information corresponding to the pressure, which is the measurement value of the pressure sensor 63, falls within a desired range when the contact surface 102 of the first workpiece 101 and the contact surface 111 of the second workpiece 110 move relative to each other in a state of being in contact with each other. The desired range is a range exceeding a predetermined lower limit value and falling below a predetermined upper limit value. The predetermined lower limit value is a value at which unevenness of the contact surface 102 of the first workpiece 101 and the contact surface 111 of the second workpiece 110 can be reduced, and the predetermined upper limit value is a value at which at least one of the first workpiece 101 and the second workpiece 110 is damaged. The reduction of the unevenness means that the surface roughness of the contact surfaces 102 and 111 is reduced.

Thus, in the unevenness reducing step 1004, the control unit 100 of the processing device 40 controls the second moving unit 62 to move the second holding portion 50 away from or close to the first holding portion 41 such that the information corresponding to the pressure measured by the pressure sensor 63 falls within the desired range, thereby controlling (adjusting) the pressure for pressing the first workpiece 101 and the second workpiece 110 against each other.

When the control unit 100 of the processing device 40 controls the first moving unit 61 to reciprocate the contact surface 102 of the first workpiece 101 and the contact surface 111 of the second workpiece 110 relatively in the horizontal direction in a state in which the contact surfaces are in contact with each other, as shown in FIG. 6, the unevenness rub against each other and wear, and the unevenness gradually decrease. Thus, in the unevenness reducing step 1004, the processing device 40 causes the first moving unit 61 to relatively move the contact surface 102 of the first workpiece 101 and the contact surface 111 of the second workpiece 110 in a state in which the contact surface 102 and the contact surface 111 are in contact with each other, thereby reducing the unevenness of at least one of the contact surface 102 of the first workpiece 101 and the contact surface 111 of the second workpiece 110. In Embodiment 1, the processing device 40 reduces unevenness of both the contact surface 102 of the first workpiece 101 and the contact surface 111 of the second workpiece 110. Reducing the unevenness of the contact surfaces 102 and 111 means reducing the surface roughness (such as the arithmetic mean roughness) of the contact surfaces 102 and 111.

In Embodiment 1, in the unevenness reducing step 1004, the control unit 100 of the processing device 40 controls the second moving unit 62 such that information corresponding to the pressures from the three (all) pressure sensors 63 is within the desired range.

### Grinding Step

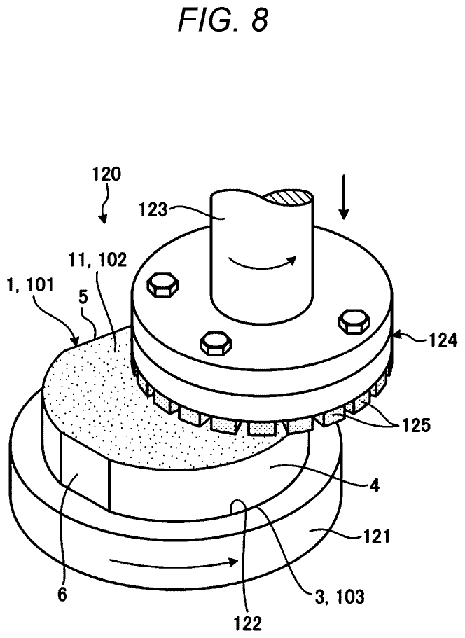

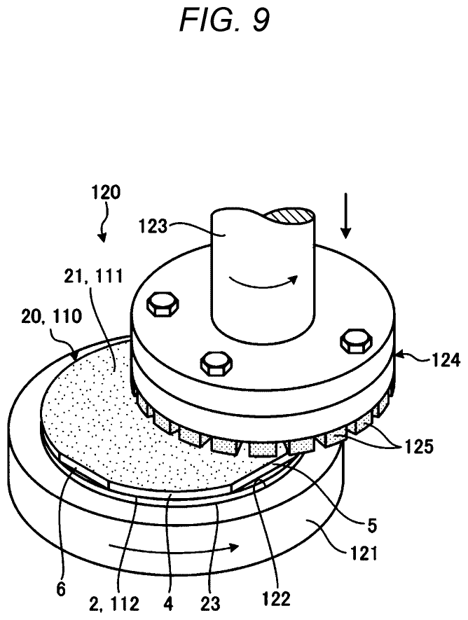

FIG. 8 is a perspective view schematically showing a state in which the first workpiece is ground in the grinding step in FIG. 3. FIG. 9 is a perspective view showing a state in which the second workpiece is ground in the grinding step in FIG. 3. The grinding step 1005 is a step of grinding the contact surface 102 or 111 of at least one of the first workpiece 101 and the second workpiece 110 with a grinding wheel 124 after the unevenness reducing step 1004. In Embodiment 1, in the grinding step 1005, the contact surfaces 102 and 111 of both the first workpiece 101 and the second workpiece 110 are ground by the grinding wheel 124. Alternatively, at least one of the contact surfaces 102 and 111 may be ground by the grinding wheel 124.

In the grinding step 1005 in Embodiment 1, a grinding device 120 suctions and holds the back surface 103 of the first workpiece 101 on a holding surface 122 of a chuck table 121. In the grinding step 1005, as shown in FIG. 8, the grinding device 120 rotates the grinding wheel 124 for grinding about the axis by a spindle 123, rotates the chuck table 121 about the axis by the spindle 123, causes a grindstone 125 of the grinding wheel 124 to abut against the contact surface 102 of the first workpiece 101 and move toward the chuck table 121 at a predetermined feed speed while supplying the grinding liquid from the grinding liquid nozzle (not shown), and grinds the contact surface 102 of the first workpiece 101 by the grindstone 125.

In the grinding step 1005, the grinding device 120 suctions and holds the back surface 112 of the second workpiece 110 on the holding surface 122 of the chuck table 121. In the grinding step 1005, as shown in FIG. 9, the grinding device 120 rotates the grinding wheel 124 for grinding about the axis by the spindle 123, rotates the chuck table 121 about the axis by the spindle 123, causes the grindstone 125 of the grinding wheel 124 to abut against the contact surface 111 of the second workpiece 110 and move toward the chuck table 121 at a predetermined feed speed while supplying the grinding liquid from the grinding liquid nozzle (not shown), and grinds the contact surface 111 of the second workpiece 110 by the grindstone 125.

As described above, the processing device 40 and the processing method according to Embodiment 1 reduce the unevenness of the contact surfaces 102 and 111 by relatively moving and rubbing the first workpiece 101 and the second workpiece 110 in a state in which the contact surface 102 of the first workpiece 101 and the contact surface 111 of the second workpiece 110 are in contact with each other. In this way, in the processing device 40 and the processing method according to Embodiment 1, since the contact surface 102 of the first workpiece 101 and the contact surface 111 of the second workpiece 110, which are made of the same materials, are rubbed against each other, a relatively soft material does not wear alone and the material is not worn out alone or the grinding force does not decrease, and the unevenness of both the first workpiece 101 and the second workpiece 110 can be reduced.

In the processing device 40 and the processing method according to Embodiment 1, since the contact surface 102 of the first workpiece 101 and the contact surface 111 of the second workpiece 110 are relatively moved and rubbed against each other in a state of being in contact with each other, the unevenness can be reduced using the unevenness removed by the grinding processing in the related art, and the wear of the grindstone 125 of the grinding wheel 124 for reducing the unevenness can be reduced, which is economical. In the processing device 40 and the processing method according to Embodiment 1, since the first workpiece 101 and the second workpiece 110 are ground by the grinding wheel 124 in a state in which the unevenness is reduced, the grinding amount and the grinding time can be reduced, and the wear of the grindstone 125 of the grinding wheel 124 is reduced, which is economical.

As a result, the processing device 40 and the processing method according to Embodiment 1 have an effect that the unevenness of the contact surface 102 or 111 of at least one of the first workpiece 101 and the second workpiece 110 can be economically reduced efficiently and at low cost without depending on the workpieces 101 and 110.

Since the processing device 40 and the processing method according to Embodiment 1 reduce the unevenness of the workpieces 101 and 110 by bringing the same materials into contact, one does not wear out first, the grinding force does not decrease, the workpieces grind each other, and the unevenness can be efficiently reduced. When the workpieces 101 and 110 are made of a hard material, the wear amount of the grinding wheel 124 increases when the workpieces 101 and 110 are ground by the grinding wheel 124, which increases the cost. In the processing device 40 and the processing method according to Embodiment 1, since the unevenness to be finally removed is used to grind the same material to reduce the unevenness by the unevenness, the wear amount of the grinding wheel 124 can be reduced as compared with the case in which the unevenness is ground by the grinding wheel 124, which is economical. Since the unevenness are ground with each other, the unevenness can be efficiently reduced in a short time.

In the processing device 40 and the processing method according to Embodiment 1, the extending direction of the unevenness present on the contact surface 102 of the first workpiece 101 and the extending direction of the unevenness present on the contact surface 111 of the second workpiece 110 intersect each other, so that the unevenness are prevented from being caught on each other. Accordingly, it is possible to reduce the possibility that damage such as cracking or chipping occurs in the first workpiece 101 and the second workpiece 110.

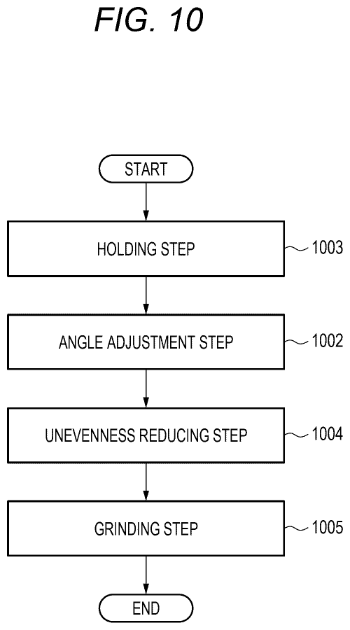

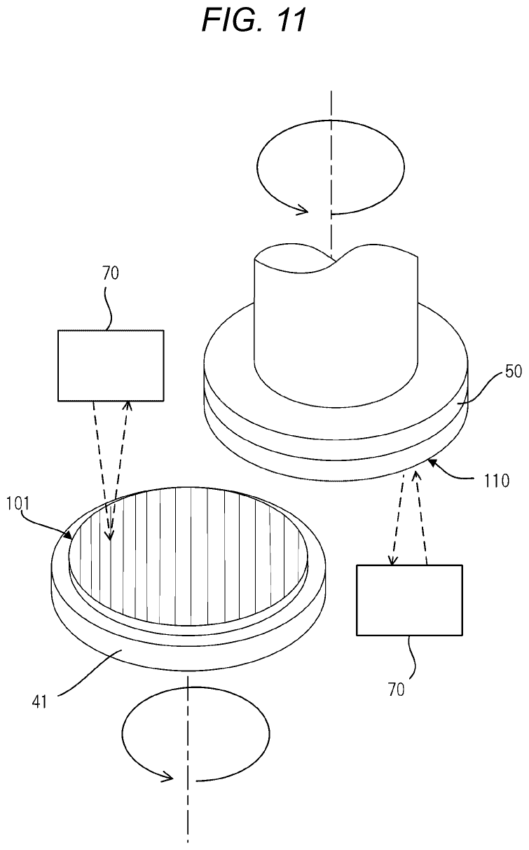

In the processing method in FIG. 3, the angle adjustment step 1002 is performed before the holding step 1003. Alternatively, as shown in FIG. 10, the angle adjustment step 1002 may be performed after the holding step 1003. When the angle adjustment step 1002 is performed after the holding step 1003, as shown in FIG. 11, in a state in which the first workpiece 101 is held by the first holding portion 41 and the second workpiece 110 is held by the second holding portion 50, captured images of the contact surface 102 of the first workpiece 101 and the contact surface 111 of the second workpiece 110 are acquired by an imaging device 70, and the extending direction of the unevenness of the contact surface 102 and the extending direction of the unevenness of the contact surface 111 are detected. Then, at least one of the first holding portion 41 and the second holding portion 50 is rotated such that the intersection angle between the extending direction of the unevenness of the contact surface 102 and the extending direction of the unevenness of the contact surface 111 becomes the predetermined angle.

### Modification of Embodiment 1

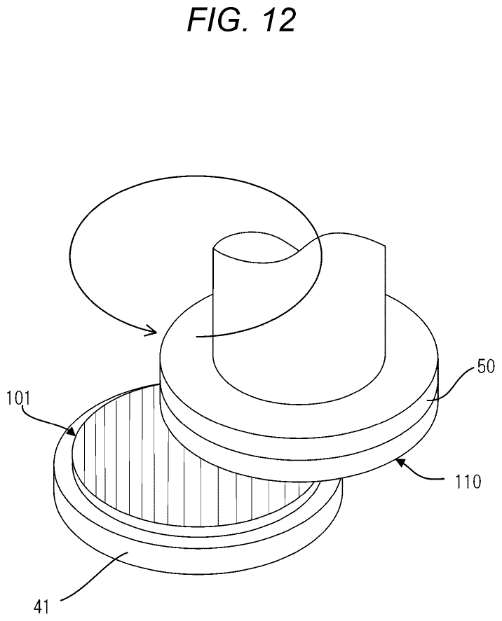

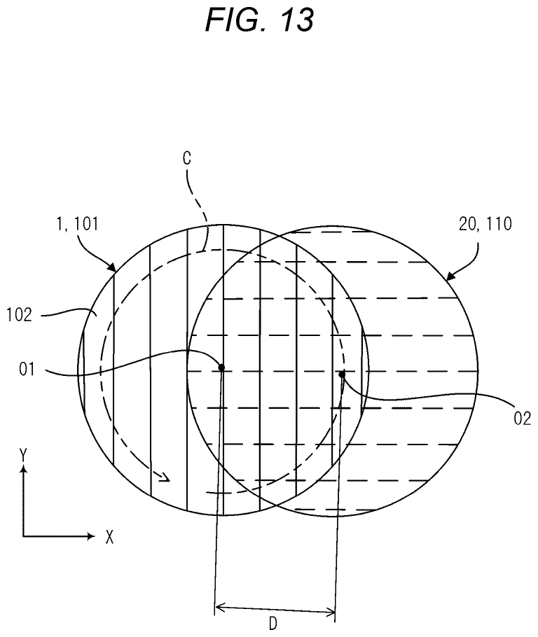

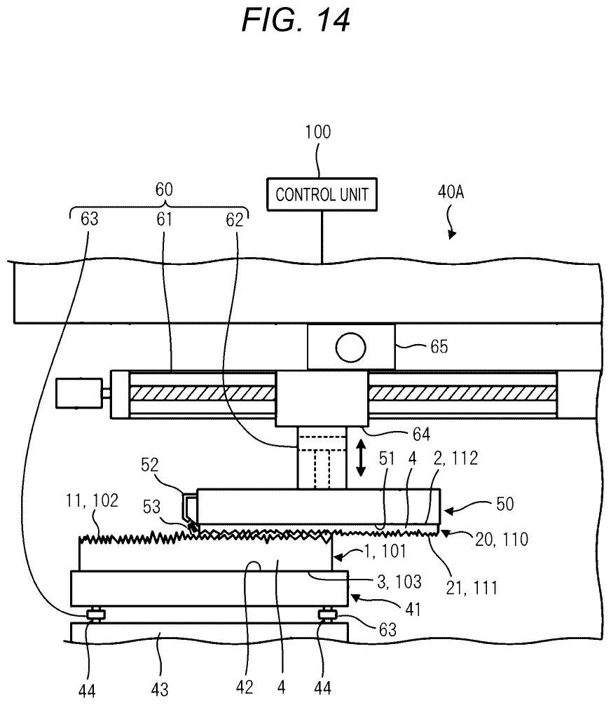

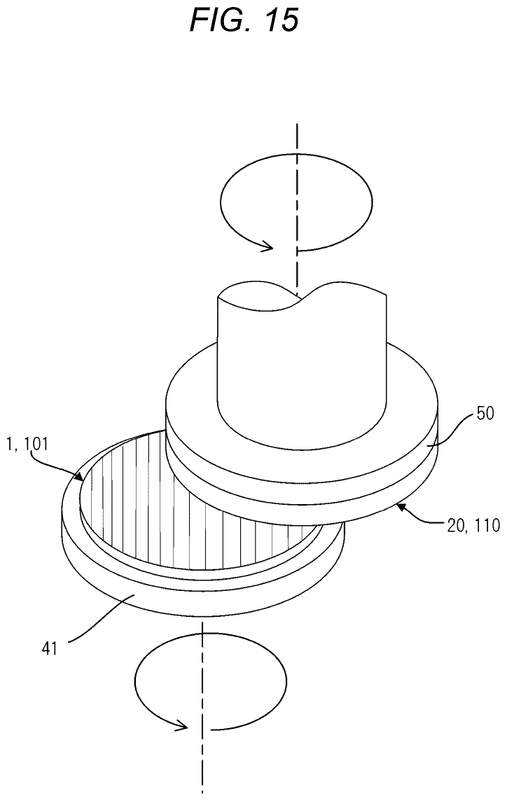

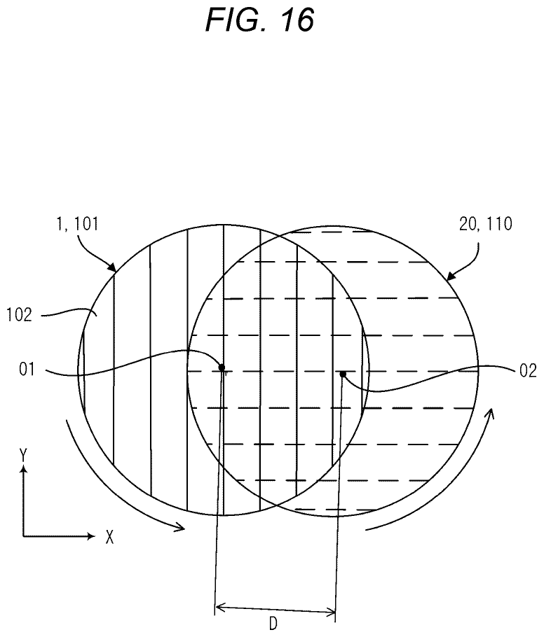

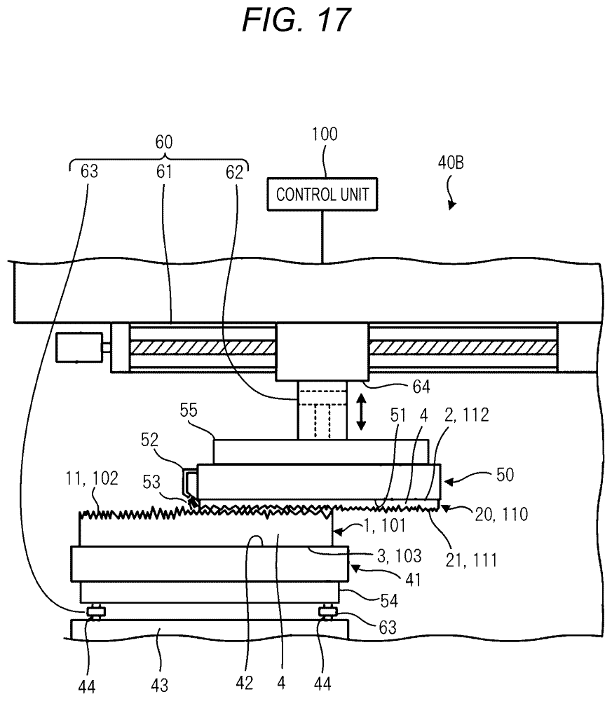

Another example of the relative movement of the second workpiece 110 with respect to the first workpiece 101 in the unevenness reducing step 1004 will be described. FIG. 12 is a perspective view schematically showing the relative movement according to Modification 1, and FIG. 13 is a plan view schematically showing the relative movement according to Modification 1. FIG. 14 is a diagram schematically showing a configuration example of a processing device used for the relative movement according to Modification 1. FIG. 15 is a perspective view schematically showing the relative movement according to Modification 2, and FIG. 16 is a plan view schematically showing the relative movement according to Modification 2. FIG. 17 is a diagram schematically showing a configuration example of a processing device used for the relative movement according to Modification 2.

In Modification 1 shown in FIGS. 12 and 13, the first workpiece 101 is provided such that the extending direction of the unevenness present on the contact surface 102 coincides with the Y direction. The second workpiece 110 is provided such that the extending direction of the unevenness present on the contact surface 111 coincides with the X direction. The first workpiece 101 and the second workpiece 110 are provided such that a center O1 of the contact surface 102 and a center O2 of the contact surface 111 are shifted in the horizontal direction. A center-to-center distance D between the center O1 of the contact surface 102 and the center O2 of the contact surface 111 is set to be less than the radius of the circular first workpiece 101 and second workpiece 110. In other words, the center-to-center distance D is set such that the center O1 of the contact surface 102 overlaps the contact surface 111 and the center O2 of the contact surface 111 overlaps the contact surface 102.

Then, the second workpiece 110 is moved circumferentially relative to the first workpiece 101 along a circle C whose center is the center O1 of the contact surface 102 of the first workpiece 101 and whose radius is the center-to-center distance D. Meanwhile, the extending direction of the unevenness of the contact surface 102 of the first workpiece 101 is fixed in the Y direction, and the extending direction of the unevenness of the contact surface 111 of the second workpiece 110 is fixed in the X direction. Accordingly, in a state in which the contact surfaces 102 and 111 are in contact with each other, the intersection angle between the extending direction of the unevenness of the contact surface 102 and the extending direction of the unevenness of the contact surface 111 is maintained at 90°, and the unevenness of the contact surface 102 and the unevenness of the contact surface 111 rub against each other and wear.

The relative movement of the first workpiece 101 and the second workpiece 110 according to Modification 1 is achieved by a processing device 40A including a third moving unit 65 as shown in FIG. 14, for example. The processing device 40A is the same as the processing device 40 in FIG. 1 except that the third moving unit 65 is provided. Assuming that the first moving unit 61 moves the second moving unit 62 in the X direction, which is one direction of the horizontal directions, the third moving unit 65 moves the first moving unit 61 in the Y direction, which is one direction of the horizontal directions and is orthogonal to the X direction. Similarly to the first moving unit 61 and the second moving unit 62, the third moving unit 65 includes a ball screw, a motor, and a guide rail.

In Modification 2 shown in FIGS. 15 and 16, similarly to Modification 1, the first workpiece 101 is provided such that the extending direction of the unevenness present on the contact surface 102 coincides with the Y direction. The second workpiece 110 is provided such that the extending direction of the unevenness present on the contact surface 111 coincides with the X direction. The first workpiece 101 and the second workpiece 110 are provided such that the center O1 of the contact surface 102 and the center O2 of the contact surface 111 are shifted in the horizontal direction. The center-to-center distance D between the center O1 of the contact surface 102 and the center O2 of the contact surface 111 is set to be less than the radius of the circular first workpiece 101 and second workpiece 110.

Then, the first workpiece 101 is rotated about the center O1 of the contact surface 102, and the second workpiece 110 is rotated about the center O2 of the contact surface 111 in the same direction and at the same speed as the first workpiece 101. Accordingly, in the state in which the contact surfaces 102 and 111 are in contact with each other, the intersection angle between the extending direction of the unevenness of the contact surface 102 and the extending direction of the unevenness of the contact surface 111 is maintained at 90°, and the unevenness of the contact surface 102 and the unevenness of the contact surface 111 rub against each other and wear.

The relative movement of the first workpiece 101 and the second workpiece 110 according to Modification 2 is achieved by a processing device 40B including a rotation drive source 54 and a rotation drive source 55 as shown in FIG. 17, for example. The processing device 40B is the same as the processing device 40 in FIG. 1 except that the processing device includes the rotation drive source 54 and the rotation drive source 55. The rotation drive source 54 rotates the first holding portion 41 about an axis parallel to the vertical direction. The rotation drive source 55 rotates the second holding portion 50 about an axis parallel to the vertical direction.

According to Modification 1 and Modification 2, the extending direction of the unevenness of the contact surface 102 and the extending direction of the unevenness of the contact surface 111 intersect each other, so that the unevenness are prevented from being caught on each other, and the possibility that damage such as cracking or chipping occurs in the first workpiece 101 and the second workpiece 110 is reduced. Further, the unevenness rub against each other in a circular motion instead of a translational motion, thereby promoting wear of the unevenness. Accordingly, the unevenness can be efficiently reduced. Further, in Modification 2, the unevenness reducing step can be performed while fixing the positions of the first workpiece 101 and the second workpiece 110, which contributes to downsizing of the processing device.

### Embodiment 2

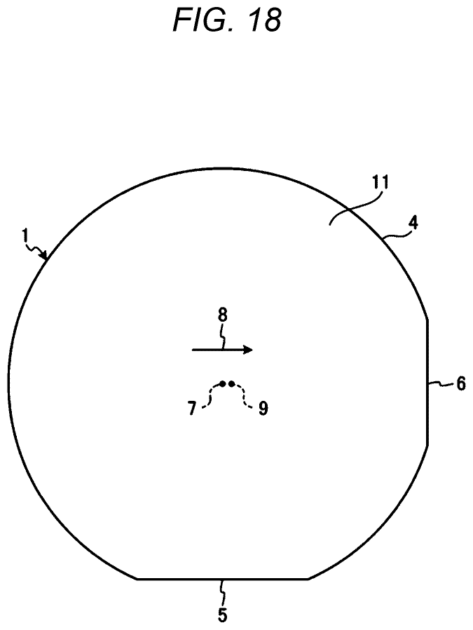

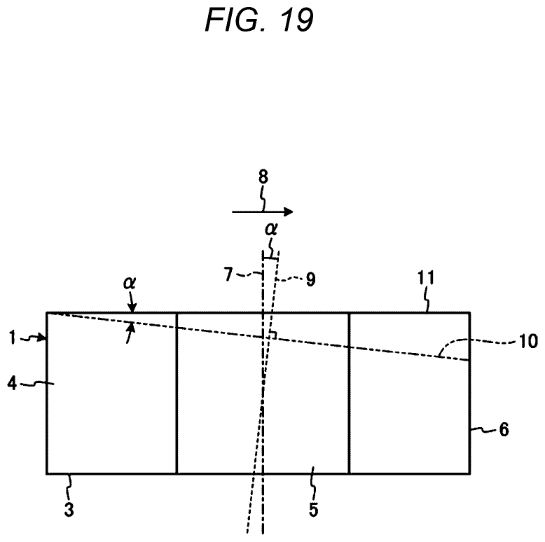

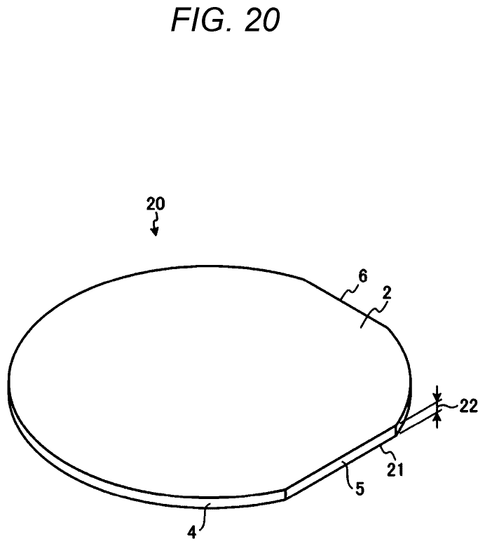

A processing method and a wafer manufacturing method according to Embodiment 2 of the present disclosure will be described with reference to the drawings. FIG. 18 is a plan view of an ingot used in the processing method and the wafer manufacturing method according to Embodiment 2. FIG. 19 is a side view of the ingot shown in FIG. 18. FIG. 20 is a perspective view of a wafer produced by the processing method and the wafer manufacturing method according to Embodiment 2. In the description of Embodiment 2, the same portions as those in Embodiment 1 are denoted by the same reference signs.

### Ingot and Wafer

FIG. 18 is a plan view of an ingot which is an example of the first workpiece 101. FIG. 19 is a side view of the ingot shown in FIG. 18. FIG. 20 is a perspective view of a wafer which is an example of the second workpiece 110.

An ingot 1 shown in FIG. 18 is a hexagonal single crystal SiC ingot formed in a columnar shape as a whole and made of silicon carbide (SiC). The ingot 1 may be made of germanium (Ge), gallium arsenide (GaAs), or silicon (Si).

As shown in FIGS. 18 and 19, the ingot 1 has a release surface 11 (corresponding to a contact surface) formed in a circular shape, a second surface 3 (corresponding to a back surface) formed in a circular shape on a side opposite to the release surface 11, and a peripheral surface 4 continuous with the outer edge of the release surface 11 and the outer edge of the second surface 3. The ingot 1 has a linear first orientation flat 5 indicating a crystal orientation on the peripheral surface 4 and a linear second orientation flat 6 orthogonal to the first orientation flat 5. The first orientation flat 5 is longer than the second orientation flat 6.

The release surface 11 of the ingot 1 is roughly ground and finish ground by a grinding device, and then polished by a polishing device to form a mirror-shaped first surface 2 (corresponding to an end surface, as shown in FIG. 20). The ingot 1 has a c-axis 9 inclined by an off angle α in an inclination direction 8 toward the second orientation flat 6 with respect to a perpendicular line 7 of the first surface 2, and a c-plane 10 orthogonal to the c-axis 9. The c-plane 10 is inclined by the off angle α with respect to the first surface 2 of the ingot 1. The inclination direction 8 of the c-axis 9 from the perpendicular line 7 is orthogonal to the extending direction of the second orientation flat 6 and parallel to the first orientation flat 5. The c-plane 10 is set innumerably in the ingot 1 at the molecular level of the ingot 1. In Embodiment 2, the off angle α is set to 1°, 4°, or 6°, and the ingot 1 can be manufactured by freely setting the off angle α within a range of, for example, 1° to 6°.

A portion of the ingot 1 on the first surface 2 side is released, and the released portion becomes a wafer 20 shown in FIG. 20. Therefore, the wafers 20 are released in order from the first surface 2 side of the ingot 1, and the thickness of the ingot 1 is reduced. That is, the ingot 1 from which the wafer 20 serving as the second workpiece has been released has the release surface 11 and the second surface 3. The release surface 11 is a surface from which the wafer 20 has been released. After the wafer 20 serving as the second workpiece has been released from the ingot 1, the release surface 11 is mirror-finished to form the first surface 2, and then the next wafer 20 is released. In the following description, the ingot 1 whose release surface 11 is mirror-finished and formed on the first surface 2 is denoted by a reference sign 1-1.

In the wafer 20 shown in FIG. 20, a portion of the ingot 1-1 including the first surface 2 is released. Therefore, the wafer 20 has the first surface 2 and a release surface 21 (corresponding to a contact surface) that is a surface released from the ingot 1-1. Therefore, the wafer 20 is made of the same material as the ingot 1. After the release surface 21 of the wafer 20 is roughly ground and finish ground by the grinding device and then polished by the polishing device, devices are formed in regions of the surface of the wafer 20 partitioned in a grid pattern by a plurality of planned dividing lines.

The device is a metal-oxide-semiconductor field-effect transistor (MOSFET), micro electro mechanical systems (MEMS), or a Schottky barrier diode (SBD), and the device is not limited to the MOSFET, the MEMS, and the SBD. The same portions of the wafer 20 as those of the ingot 1 are denoted by the same reference signs, and the description thereof will be omitted.

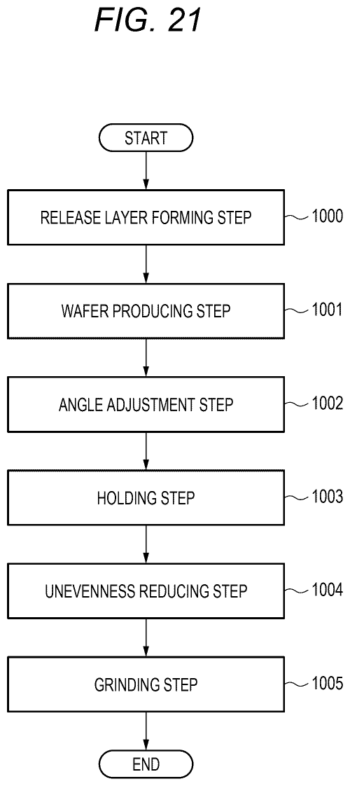

FIG. 21 is a flowchart showing a method for producing the wafer 20 by releasing a portion of the ingot 1-1 having the mirror-shaped first surface 2 as the wafer 20 to be produced. As shown in FIG. 21, the method for producing the wafer 20 includes a release layer forming step 1000 and a wafer producing step 1001.

### Release Layer Forming Step

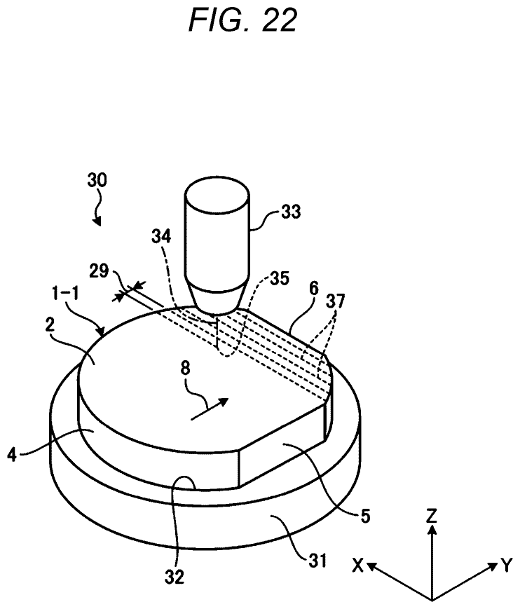

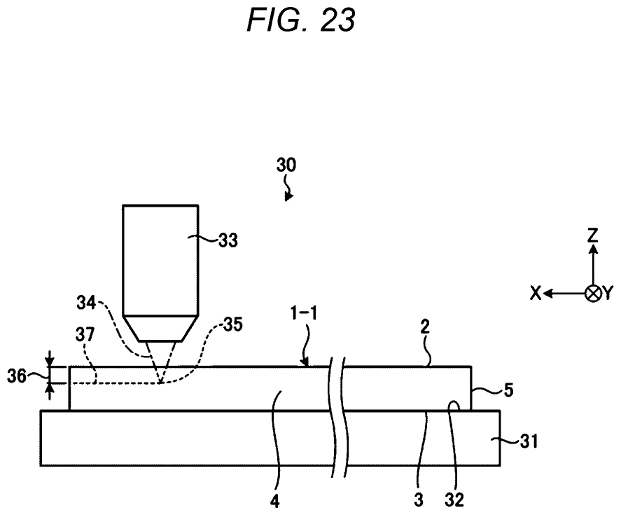

FIG. 22 is a perspective view schematically showing a release layer forming step in FIG. 21. FIG. 23 is a side view schematically showing the release layer forming step in FIG. 21. The release layer forming step 1000 is a step of positioning a focal point 35 of a laser beam 34 having a wavelength that is transmittable through the ingot 1-1 having the first surface 2 at a depth 36 corresponding to a thickness 22 (shown in FIG. 20) of the wafer 20 to be produced from the first surface 2 of the ingot 1-1, irradiating the ingot 1-1 with the laser beam 34, and forming a release layer 37 that releases the wafer 20 spreading in a direction parallel to the first surface 2 and the second surface 3 of the ingot 1.

In the release layer forming step 1000, a wafer producing device 30 suctions and holds the second surface 3 of the ingot 1-1 on a holding surface 32 of a holding table 31. In the release layer forming step 1000, the wafer producing device 30 controls a laser beam irradiation unit 33 to position the focal point 35 of the pulsed laser beam 34 having a wavelength that is transmittable through the ingot 1-1 at the depth 36 corresponding to the thickness 22 of the wafer 20 to be produced from the first surface 2 of the ingot 1-1, and to apply the pulsed laser beam 34 while relatively moving the laser beam irradiation unit 33 and the holding table 31 in an X-axis direction parallel to the horizontal direction. In Embodiment 2, the X-axis direction and the second orientation flat 6 are positioned parallel to each other.

When the ingot 1-1 is irradiated with the laser beam 34, since the laser beam 34 has a wavelength that is transmittable through the ingot 1-1, a modified portion is formed along the X-axis direction at a position inside the ingot at the depth 36 from the first surface 2, and cracks extending from the modified portion along the c-plane 10 are generated. In the modified portion, SiC is released into silicon (Si) and carbon (C) by irradiation with the pulsed laser beam 34, and the pulsed laser beam 34 with which irradiation is to be performed next is absorbed by the previously formed C, so that SiC is released into Si and C in a chain reaction manner. The modified portion refers to a region in which the density, refractive index, mechanical strength, or other physical properties are different from those of the surroundings, and examples thereof include a melt-treated region, a crack region, an insulation breakdown region, a refractive index change region, and a region in which these regions are mixed. The modified portion has lower mechanical strength and the like than other portions of the ingot 1-1. In this way, when the ingot 1-1 is irradiated with the pulsed laser beam 34 having a wavelength that is transmittable through the ingot 1-1, the release layer 37 including the modified portion and cracks formed along the c-plane 10 from the modified portion is formed in the ingot.

In the release layer forming step 1000, when the release layer 37 is formed over the entire length of the second orientation flat 6 of the ingot 1-1, the wafer producing device 30 temporarily stops the irradiation with the laser beam 34 from the laser beam irradiation unit 33, and relatively moves (hereinafter referred to as index feeding) the laser beam irradiation unit 33 and the holding table 31 by a predetermined moving distance 29 (shown in FIG. 22) along the horizontal direction and along the Y-axis direction orthogonal to the X-axis direction. In the release layer forming step 1000, after the index feeding, the wafer producing device 30 positions the focal point 35 of the laser beam 34 at the depth 36 described above, and performs irradiation with the laser beam 34 while relatively moving the laser beam irradiation unit 33 and the holding table 31 in the X-axis direction to form the release layer 37.

In the release layer forming step 1000, the wafer producing device 30 alternately repeats the irradiation with the laser beam 34 while relatively moving the laser beam irradiation unit 33 and the holding table 31 along the X-axis direction and the index feeding until the release layer 37 is formed on the entire lower side of the first surface 2, thereby forming the release layer 37 on the entire lower side of the first surface 2 of the ingot 1-1.

### Wafer Producing Step

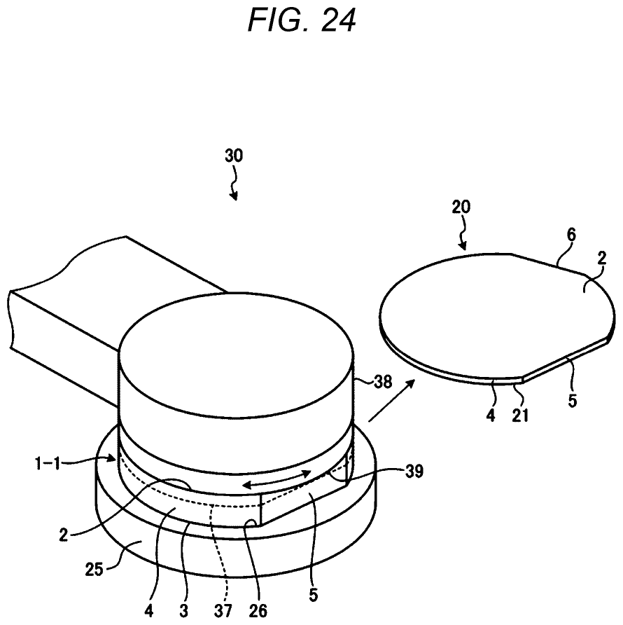

FIG. 24 is a perspective view schematically showing the wafer producing step in FIG. 21. The wafer producing step 1001 is a step of producing the wafer 20 by releasing the wafer 20 to be produced using the release layer 37 as a starting point from the ingot 1-1 after performing the release layer forming step 1000.

In the wafer producing step 1001, the wafer producing device 30 suctions and holds the second surface 3 of the ingot 1-1 having the release layer 37 formed thereon on the holding surface 26 of the second holding table 25. The wafer producing device 30 retracts the laser beam irradiation unit 33 from the second surface 3 of the ingot 1-1 held on the second holding table 25. Then, as shown in FIG. 24, the wafer producing device 30 suctions and holds the first surface 2 of the ingot 1-1 on a suction surface 39, which is the lower surface of the holding portion 38. The wafer producing device 30 applies AC power for a predetermined time to an ultrasonic vibrator in the holding portion 38 suctioning and holding the first surface 2 of the ingot 1-1 to ultrasonically vibrate the holding portion 38 while supplying a liquid to the release layer 37 by a liquid supply portion (not shown).

In the wafer producing step 1001, the wafer producing device 30 ultrasonically vibrates the holding portion 38 to transmit the ultrasonic vibration to the first surface 2 of the ingot 1-1, thereby applying the ultrasonic vibration. Then, the ultrasonic vibration stimulates the release layer 37, and the ingot 1-1 is divided with the release layer 37 as a starting point to release the wafer 20 to be produced from the ingot 1-1.

In the wafer producing step 1001, when the wafer producing device 30 applies AC power to the ultrasonic vibrator of the holding portion 38 for a predetermined time to ultrasonically vibrate the holding portion 38 to release the wafer 20 to be produced from the ingot 1-1, the application of AC power to the ultrasonic vibrator is stopped, and the holding portion 38 is retracted from above the second holding table 25 to release the wafer 20 from the ingot 1-1. Various methods can be used as long as the wafer 20 can be released from the ingot 1-1 with the release layer 37 as a starting point, and for example, the release may be performed by applying ultrasonic vibration in a state in which the ingot 1-1 is placed in a water tank, or the release may be performed without using ultrasonic vibration.

In this way, the wafer 20 is released from the first surface 2 side with the release layer 37 as a starting point, so that the ingot 1 having the release surface 11 (also corresponding to the contact surface) is formed, and the wafer 20 having the release surface 21 (also corresponding to the contact surface) is formed. The release surface 11 of the ingot 1 is a surface from which the wafer 20 is released in the wafer producing step 1001, and the release surface 21 of the wafer 20 is a surface released from the ingot 1 in the wafer producing step 1001. The release surfaces 11 and 21 formed by the release layer 37 are formed with unevenness linearly extending in one direction in the surface, and the extending direction of the unevenness corresponds to the scanning direction (the X-axis direction in FIG. 22) of the laser beam 34 in the release layer forming step 1000. Therefore, the extending direction of the unevenness of the release surfaces 11 and 21 is perpendicular to the first orientation flat 5 and parallel to the second orientation flat 6.

### Angle Adjustment Step

In the angle adjustment step 1002, the posture angle of the ingot 1 when the ingot 1 is provided on the first holding portion 41 of the processing device 40 and the posture angle of the wafer 20 when the wafer 20 is provided on the second holding portion 50 of the processing device 40 are set such that the extending direction of the unevenness present on the release surface 11 of the ingot 1 and the extending direction of the unevenness present on the release surface 21 of the wafer 20 intersect each other. The extending direction of the unevenness of the release surfaces 11 and 21 can be detected based on the striped pattern appearing in the captured image of the release surfaces 11 and 21, similarly to the processing method according to Embodiment 1. The extending direction of the unevenness of the release surfaces 11 and 21 can also be detected based on the outer peripheral shapes of the ingot 1 and the wafer 20.

As described above, the extending direction of the unevenness of the release surfaces 11 and 21 is perpendicular to the relatively long first orientation flat 5 and parallel to the relatively short second orientation flat 6. Therefore, by detecting the first orientation flat 5 and/or the second orientation flat 6 based on the captured images of the ingot 1 and the wafer 20, the extending direction of the unevenness of the release surfaces 11 and 21 can be detected. At least one of the ingot 1 and the wafer 20 is rotated such that the intersection angle between the extending direction of the unevenness of the release surface 11 and the extending direction of the unevenness of the release surface 21 becomes a predetermined angle. Then, the ingot 1 and the wafer 20 are conveyed to the first holding portion 41 and the second holding portion 50 by an appropriate conveying device such as a robot arm while maintaining the set intersection angle.

### Holding Step

The holding step 1003 is a step of holding the ingot 1 from which the wafer 20 is released by the first holding portion 41 and holding the wafer 20 released from the ingot 1 by the second holding portion 50. In the holding step 1003, the control unit 100 of the processing device 40 controls the moving mechanism 60 to position the second holding portion 50 at the retracted position and to raise the second holding portion 50. In the holding step 1003, the control unit 100 of the processing device 40 controls the first holding portion 41 and the second holding portion 50 to suction and hold the second surface 3 of the ingot 1 on the holding surface 42 of the first holding portion 41 and to suction and hold the first surface 2 of the wafer 20 on the holding surface 51 of the second holding portion 50. In this way, in Embodiment 2, the ingot 1 which is the first workpiece is an ingot obtained by releasing the wafer 20 in the wafer producing step 1001, and the wafer 20 which is the second workpiece is a wafer produced in the wafer producing step 1001.

### Unevenness Reducing Step

The unevenness reducing step 1004 is a step of reducing the unevenness of the release surface 11 or 21 of at least one of the ingot 1 and the wafer 20 by relatively moving the first holding portion 41 and the second holding portion 50 in a state in which the release surface 11 of the ingot 1 from which the wafer 20 is released is in contact with the release surface 21 of the wafer 20 released from the ingot 1. In Embodiment 2, the unevenness reducing step 1004 is a step of reducing both the unevenness of the release surface 11 of the ingot 1 and the unevenness of the release surface 21 of the wafer 20.

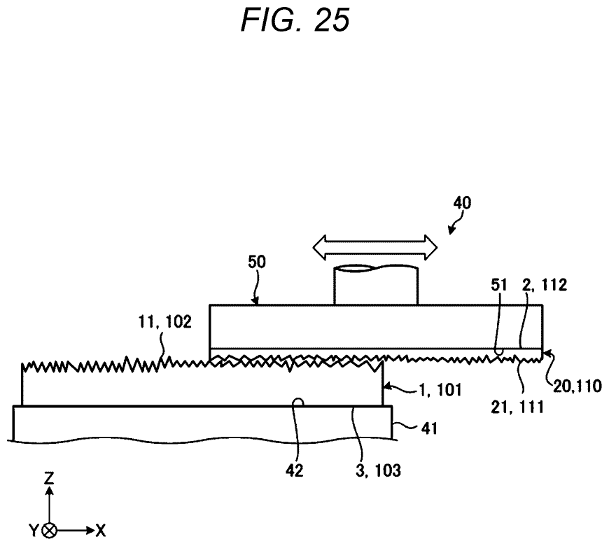

In the unevenness reducing step 1004, as shown in FIG. 25, the control unit 100 of the processing device 40 controls the first moving unit 61 and the second moving unit 62 to bring the release surface 21 of the wafer 20 held by the second holding portion 50 into contact with the release surface 11 of the ingot 1 held by the first holding portion 41. The release surfaces 11,21 come into contact with each other in a state in which the extending direction of the unevenness of the release surface 11 and the extending direction of the unevenness of the release surface 21 intersect at the predetermined angle set in the angle adjustment step 1002.

In the unevenness reducing step 1004, as shown in FIG. 1, the control unit 100 of the processing device 40 controls the first moving unit 61 to relatively move the ingot 1 and the wafer 20 for a predetermined time while supplying the liquid 53 from the liquid supply nozzle 52 in a state in which the ingot 1 and the release surfaces 11 and 21 of the wafer 20 are in contact with each other. In Embodiment 2, in the unevenness reducing step 1004, the control unit 100 of the processing device 40 controls the first moving unit 61 to reciprocate the wafer 20 relative to the ingot 1 in the horizontal direction.

In Embodiment 2, in the unevenness reducing step 1004, the control unit 100 of the processing device 40 adjusts the distance between the first holding portion 41 and the second holding portion 50 by controlling the second moving unit 62 such that the information corresponding to the pressure, which is the measurement value of the pressure sensor 63, falls within a desired range when the release surface 11 of the ingot 1 and the release surface 21 of the wafer 20 are relatively moved in a state of being in contact with each other. The desired range is a range exceeding a predetermined lower limit value and falling below a predetermined upper limit value. The predetermined lower limit value is a value at which the unevenness of the ingot 1 and the release surfaces 11 and 21 of the wafer 20 can be reduced, and the predetermined upper limit value is a value at which at least one of the wafer 20 and the ingot 1 is damaged. The reduction of the unevenness means that the surface roughness of the release surfaces 11 and 21 is reduced.

Thus, in the unevenness reducing step 1004, the control unit 100 of the processing device 40 controls the second moving unit 62 to move the second holding portion 50 away from or close to the first holding portion 41 such that the information corresponding to the pressure measured by the pressure sensor 63 falls within the desired range, thereby controlling (adjusting) the pressure for pressing the ingot 1 and the wafer 20 against each other.

In the unevenness reducing step 1004, when the control unit 100 of the processing device 40 controls the first moving unit 61 to reciprocate the release surface 11 of the ingot 1 and the release surface 21 of the wafer 20 in the horizontal direction relative to each other in a state in which the release surface 11 and the release surface 21 are in contact with each other, the unevenness rub against each other and wear, and the unevenness gradually decrease. Thus, in the unevenness reducing step 1004, the processing device 40 causes the first moving unit 61 to relatively move the release surface 11 of the ingot 1 and the release surface 21 of the wafer 20 in a state in which the release surface 11 of the ingot 1 and the release surface 21 of the wafer 20 are in contact with each other, thereby reducing the unevenness of at least one of the release surface 11 of the ingot 1 and the release surface 21 of the wafer 20. In Embodiment 2, the processing device 40 reduces the unevenness of both the release surface 11 of the ingot 1 and the release surface 21 of the wafer 20. Reducing the unevenness of the release surfaces 11 and 21 means reducing the surface roughness (such as the arithmetic mean roughness) of the release surfaces 11 and 21.

In Embodiment 2, in the unevenness reducing step 1004, the control unit 100 of the processing device 40 controls the second moving unit 62 such that information corresponding to the pressures from the three (all) pressure sensors 63 is within the desired range.

### Grinding Step

The grinding step 1005 is a step of grinding the release surface 11 or 21 of at least one of the ingot 1 and the wafer 20 with the grinding wheel 124 after the unevenness reducing step 1004. In Embodiment 2, in the grinding step 1005, the release surfaces 11 and 21 of both the ingot 1 and the wafer 20 are ground by the grinding wheel 124. Alternatively, in the present disclosure, at least one of the release surfaces 11 and 21 may be ground by the grinding wheel 124.

In Embodiment 2, in the grinding step 1005, the grinding device 120 suctions and holds the second surface 3 of the ingot 1 on the holding surface 122 of the chuck table 121. In the grinding step 1005, as shown in FIG. 8, the grinding device 120 rotates the grinding wheel 124 for grinding about the axis by the spindle 123, rotates the chuck table 121 about the axis by the spindle 123, causes the grindstone 125 of the grinding wheel 124 to abut against the release surface 11 of the ingot 1 and move toward the chuck table 121 at a predetermined feed speed while supplying the grinding liquid from the grinding liquid nozzle (not shown), and grinds the release surface 11 of the ingot 1 by the grindstone 125.

In the grinding step 1005, a surface protective tape 23 is attached to the first surface 2 of the wafer 20, and the grinding device 120 suctions and holds the first surface 2 of the wafer 20 on the holding surface 122 of the chuck table 121 via the surface protective tape 23. In the grinding step 1005, as shown in FIG. 9, the grinding device 120 rotates the grinding wheel 124 for grinding about the axis by the spindle 123, rotates the chuck table 121 about the axis by the spindle 123, causes the grindstone 125 of the grinding wheel 124 to abut against the release surface 21 of the wafer 20 and move toward the chuck table 121 at a predetermined feed speed while supplying the grinding liquid from the grinding liquid nozzle (not shown), and grinds the release surface 21 of the wafer 20 by the grindstone 125.

Thereafter, the release surface 11 of the ingot 1 is finish ground and polished to form the first surface 2. Thereafter, the wafer 20 is released from the first surface 2 side of the ingot 1-1 again. In this way, the thicknesses of the ingots 1 and 1-1 are reduced as the wafer 20 is released, and the release layer 37 is formed until the thicknesses of the ingots 1 and 1-1 reach a predetermined thickness and a portion is released as the wafer 20. The release surface 21 of the wafer 20 is finish ground and polished to form devices on the surface.

By the processing method and the wafer manufacturing method according to Embodiment 2, the unevenness of the release surfaces 11 and 21 are reduced by relatively moving and rubbing the release surface 11 of the ingot 1 and the release surface 21 of the wafer 20 in a state in which the release surface 11 and the release surface 21 are in contact with each other. In this way, in the processing device 40 and the unevenness reducing method according to Embodiment 2, since the release surface 11 of the ingot 1 and the release surface 21 of the wafer 20, which are made of the same materials, are rubbed against each other, a relatively soft material does not wear alone and the material is not worn out alone or the grinding force does not decrease, and the unevenness of both the ingot 1 and the wafer 20 can be reduced.

In the processing method and the wafer manufacturing method according to Embodiment 2, since the release surface 11 of the ingot 1 and the release surface 21 of the wafer 20 are relatively moved and rubbed against each other in a state of being in contact with each other, the unevenness can be reduced using the unevenness removed by the grinding processing in the related art, and the wear of the grindstone 125 of the grinding wheel 124 for reducing the unevenness can be reduced, which is economical. In the processing method and the wafer manufacturing method according to Embodiment 2, since the ingot 1 and the wafer 20 are ground by the grinding wheel 124 in a state in which the unevenness is reduced, the grinding amount and the grinding time can be reduced, and the wear of the grindstones 125 of the grinding wheel 124 is reduced, which is economical.

As a result, in the processing method and the wafer manufacturing method according to Embodiment 2, the unevenness of at least one release surface of the release surface 11 of the ingot 1 and the release surface 21 of the wafer 20 after release can be economically reduced.

In particular, in the processing method and the wafer manufacturing method according to Embodiment 2, since the ingot 1 and the wafer 20 are made of SiC harder than Si or the like, the wear of the grindstones 125 of the grinding wheel 124 can be further reduced, and the unevenness of the release surfaces 11 and 21 can be economically reduced.

In the processing method and the wafer manufacturing method according to Embodiment 2, since the unevenness of the ingot 1 and the unevenness of the wafer 20 are reduced by bringing the same materials into contact with each other, one does not wear out first, the grinding force does not decrease, the ingot 1 and the wafer 20 grind each other, and the unevenness can be efficiently reduced. When the ingot 1 and the wafer 20 are made of hard materials, the wear amount of the grinding wheel 124 increases when the ingot 1 and the wafer 20 are ground by the grinding wheel 124, which increases the cost. In the present disclosure, since the unevenness to be finally removed is used to grind the same material to reduce the unevenness by the unevenness, the wear amount of the grinding wheel 124 can be reduced as compared with the case in which the unevenness is ground by the grinding wheel 124, which is economical. Since the unevenness are ground with each other, the unevenness can be efficiently reduced in a short time.

In the processing method and the wafer manufacturing method according to Embodiment 2, the extending direction of the unevenness of the release surface 11 of the ingot 1 and the extending direction of the unevenness of the release surface 21 of the wafer 20 intersect each other, so that the unevenness are prevented from being caught on each other. Accordingly, it is possible to reduce the possibility that damage such as cracking or chipping occurs in the ingot 1 and the wafer 20.

In Embodiment 2, the holding table 31 used in the release layer forming step 1000, the second holding table 25 used in the wafer producing step 1001, and the first holding portion 41 used in the unevenness reducing step 1004 are different from one another. The holding portion 38 used in the wafer producing step 1001 and the second holding portion 50 are different from each other. However, the holding table 31 used in the release layer forming step 1000 and the second holding table 25 that holds the ingot 1 in the wafer producing step 1001 may be used as the first holding portion 41 in the unevenness reducing step 1004, and the holding portion 38 used for holding the wafer 20 released in the wafer producing step 1001 may be used as the second holding portion 50 in the unevenness reducing step 1004. In this case, the size of the device used in the unevenness reduction method according to Embodiment 2 can be reduced. Further, since the extending direction of the unevenness present on the release surface 11 of the ingot 1 and the release surface 21 of the wafer 20 corresponds to the scanning direction (the X-axis direction in FIG. 22) of the laser beam 34 in the release layer forming step 1000, the detection of the extending direction of the unevenness in the angle adjustment step 1002 can be omitted, thereby simplifying the manufacturing process.

In the processing method in FIG. 21, the angle adjustment step 1002 is performed before the holding step 1003. Alternatively, the angle adjustment step 1002 may be performed after the holding step 1003. When the angle adjustment step 1002 is performed after the holding step 1003, in a state in which the ingot 1 is held by the first holding portion 41 and the wafer 20 is held by the second holding portion 50, at least one of the first holding portion 41 and the second holding portion 50 is rotated such that the intersection angle between the extending direction of the unevenness present on the release surface 11 of the ingot 1 and the extending direction of the unevenness present on the release surface 21 of the wafer 20 becomes a predetermined angle.

The relative movement of the ingot 1 and the wafer 20 in the unevenness reducing step 1004 may be a circular motion along the circle C centered on the center O1 of the release surface 11 of the ingot 1 and having a radius less than the radius of the ingot 1 and the wafer 20 as in Modification 1 of Embodiment 1 shown in FIGS. 12 and 13, or may be a circular motion in which the ingot 1 and the wafer 20 are rotated in the same direction and at the same speed as in Modification 2 of Embodiment 1 shown in FIGS. 15 and 16.

### Modification of Embodiment 2

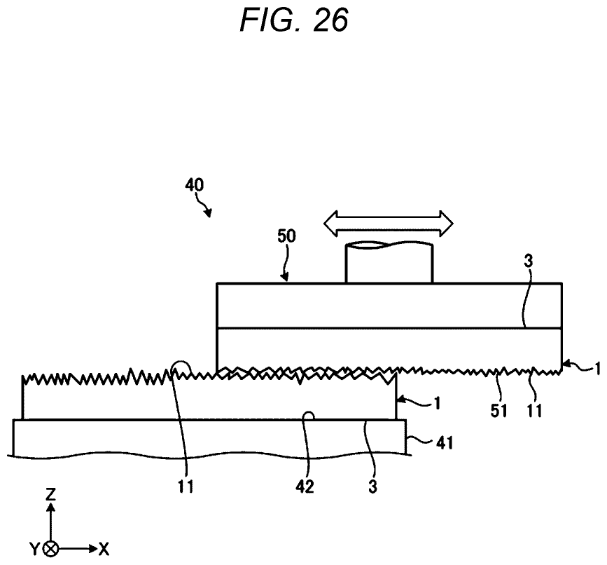

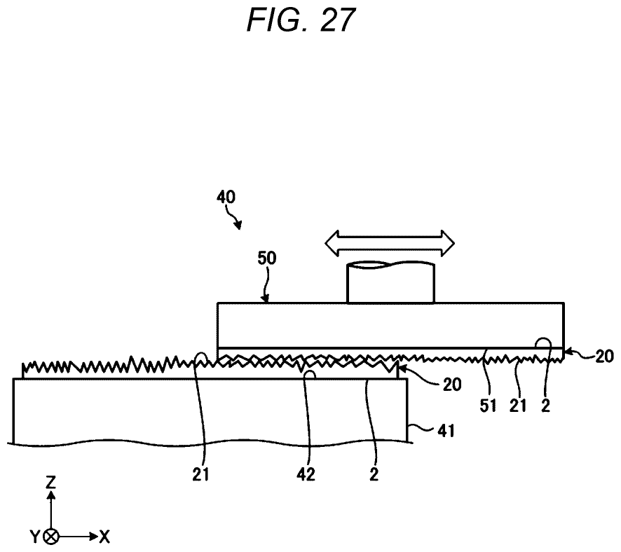

FIG. 26 is a side view schematically showing Modification 1 of the processing method according to Embodiment 2. FIG. 27 is a side view schematically showing Modification 2 of the processing method according to Embodiment 2. In FIGS. 26 and 27, the same portions as those in Embodiment 1 are denoted by the same reference signs, and the description thereof will be omitted.

In Modification 1, in the holding step 1003, the processing device 40 suctions and holds the second surface 3 of the ingot 1 on the holding surface 42 of the first holding portion 41, and suctions and holds the second surface 3 of the ingot 1 on the holding surface 51 of the second holding portion 50. That is, both the first workpiece and the second workpiece are the ingots 1. In the unevenness reducing step 1004, as shown in FIG. 26, the processing device 40 brings the release surfaces 11 of the ingots 1 into contact with each other and moves the second holding portion 50 in the horizontal direction to relatively move the ingot 1 held by the first holding portion 41 and the ingot 1 held by the second holding portion 50. With respect to one ingot 1, the relative movement of the other ingot 1 may be a circular motion along the circle C centered on the center O1 of the release surface 11 of the one ingot 1 and having a radius less than the radius of the ingot 1 as in Modification 1 of Embodiment 1 shown in FIGS. 12 and 13, or may be a circular motion in which the one ingot 1 and the other ingot 1 are rotated in the same direction and at the same speed as in Modification 2 of Embodiment 1 shown in FIGS. 15 and 16.

In Modification 2, in the holding step 1003, the processing device 40 suctions and holds the first surface 2 of the wafer 20 on the holding surface 42 of the first holding portion 41, and suctions and holds the first surface 2 of the wafer 20 on the holding surface 51 of the second holding portion 50. That is, both the first workpiece and the second workpiece are the wafers 20. Then, in the unevenness reducing step 1004, as shown in FIG. 27, the processing device 40 brings the release surfaces 21 of the wafers 20 into contact with each other and moves the second holding portion 50 in the horizontal direction to relatively move the wafer 20 held by the first holding portion 41 and the wafer 20 held by the second holding portion 50. With respect to one wafer 20, the relative movement of the other wafer 20 may be a circular motion along the circle C centered on the center O1 of the release surface 21 of the one wafer 20 and having a radius less than the radius of the wafer as in Modification 1 of Embodiment 1 shown in FIGS. 12 and 13, or may be a circular motion in which the one wafer 20 and the other wafer 20 are rotated in the same direction and at the same speed as in Modification 2 of Embodiment 1 shown in FIGS. 15 and 16.

In this way, in the unevenness reducing step 1004 of the processing method according to Embodiment 2, a combination of the first workpiece and the second workpiece is any one of a combination of the ingot 1 and the ingot 1, a combination of the wafer 20 and the wafer 20, and a combination of the ingot 1 and the wafer 20, and the contact surfaces (the release surface 11 of the ingot 1 and the release surface 21 of the wafer 20) of the first workpiece and the second workpiece are relatively moved in a state of being in contact with each other. Accordingly, the unevenness of the release surface 11 of the ingot 1 and the release surface 21 of the wafer 20 can be reduced.

The present disclosure is not limited to the above embodiments. That is, various modifications can be made without departing from the gist of the present disclosure. For example, in Embodiment 2 and the like described above, in the unevenness reducing step 1004, the unevenness of the release surfaces 11 and 21 of both the ingot 1 or the wafer 20 serving as the first workpiece and the ingot 1 or the wafer 20 serving as the second workpiece are reduced. Alternatively, the unevenness of the contact surface 102 or 111 of at least one of the first workpiece 101 and the second workpiece 110 may be reduced.

The present specification describes at least the following matters. (1) A processing method for a workpiece, the processing method including:
holding a first workpiece on a first holding portion and holding a second workpiece made of the same material as the first workpiece on a second holding portion; and
relatively moving the first workpiece and the second workpiece in an in-plane direction of a contact surface of the first workpiece and a contact surface of the second workpiece in a state in which the first workpiece and the second workpiece are in contact with each other to reduce unevenness of at least one of the contact surface of the first workpiece and the contact surface of the second workpiece,
in which, in the moving, the first workpiece and the second workpiece are brought into contact with each other such that an extending direction of the unevenness present on the contact surface of the first workpiece and an extending direction of the unevenness present on the contact surface of the second workpiece intersect each other. (2) The processing method according to (1), further including
detecting, before or after the holding, the extending direction of the unevenness of the first workpiece and the extending direction of the unevenness of the second workpiece and adjusting a posture angle of at least one of the first workpiece and the second workpiece such that the extending direction of the unevenness of the first workpiece and the extending direction of the unevenness of the second workpiece intersect each other. (3) The processing method according to (2),
in which, in the detecting, outer peripheral shapes of the first workpiece and the second workpiece are detected, and the extending direction of the unevenness of the first workpiece and the extending direction of the unevenness of the second workpiece are detected based on the outer peripheral shapes. (4) The processing method according to (2),
in which, in the detecting, the contact surface of the first workpiece and the contact surface of the second workpiece are irradiated with light, reflected light reflected by the contact surface of the first workpiece and the contact surface of the second workpiece is detected, and the extending direction of the unevenness of the first workpiece and the extending direction of the unevenness of the second workpiece are detected based on the reflected light. (5) The processing method according to claim 1, further including:
before the holding,
forming a release layer in the ingot by positioning a focal point of a laser beam having a wavelength that is transmittable through the ingot inside the ingot and scanning the ingot with the laser beam;
producing a wafer by releasing the wafer from the ingot with the release layer as a starting point,
in which the first workpiece is the ingot and the contact surface of the first workpiece is a release surface from which the wafer is released in the producing, or the first workpiece is the wafer and the contact surface of the first workpiece is a release surface released from the ingot in the producing,
in which the second workpiece is the ingot and the contact surface of the second workpiece is a release surface from which the wafer is released in the producing, or the second workpiece is the wafer and the contact surface of the second workpiece is a release surface released from the ingot in the producing,
in which the extending direction of the unevenness of the first workpiece and the extending direction of the unevenness of the second workpiece are scanning directions of the laser beam with respect to the first workpiece and the second workpiece in the forming, and
in which, in the moving, a combination of the first workpiece and the second workpiece is any one of a combination of the ingot and the ingot, a combination of the wafer and the wafer, and a combination of the ingot and the wafer, and the first workpiece and the second workpiece are brought into contact with each other. (6) The processing method according to (1) or (2),
in which, in the moving, the extending direction of the unevenness of the first workpiece and the extending direction of the unevenness of the second workpiece are fixed, and one of the first workpiece and the second workpiece is circumferentially moved relative to the other. (7) The processing method according to (1) or (2),
in which, in the moving, the first workpiece and the second workpiece are rotated in the same direction and at the same speed in a state in which a center of the contact surface of the first workpiece is shifted with respect to a center of the contact surface of the second workpiece in the in-plane direction. (8) A processing device including:
a first holding portion configured to hold a first workpiece;
a second holding portion configured to hold a second workpiece made of the same material as the first workpiece held by the first holding portion so as to face the first workpiece held by the first holding portion; and
a moving mechanism configured to relatively move the first holding portion and the second holding portion in an in-plane direction of a contact surface of the first workpiece and a contact surface of the second workpiece in a state in which the first workpiece held by the first holding portion and the second workpiece held by the second holding portion are in contact with each other,
in which the moving mechanism relatively moves the first holding portion and the second holding portion so as to maintain a state in which a first direction defined in the contact surface of the first workpiece held by the first holding portion and a second direction defined in the contact surface of the second workpiece held by the second holding portion intersect each other. (9) A wafer manufacturing method for manufacturing a wafer having a thickness less than a thickness of an ingot from the ingot, the wafer manufacturing method including:
a release layer forming step of forming a release layer inside the ingot by positioning a focal point of a laser beam having a wavelength that is transmittable through the ingot inside the ingot and scanning the ingot with the laser beam;
a wafer producing step of releasing the wafer from the ingot with the release layer as a starting point; and
an unevenness reducing step of reducing unevenness of a release surface of the wafer,
in which, in the unevenness reducing step, the wafer and the ingot or the other wafer are moved relative to each other in a state in which the release surface of the wafer is in contact with a release surface of the ingot or a release surface of the other wafer to which the unevenness reducing step is not performed to reduce the unevenness of the release surface of the wafer, and
in which, in the unevenness reducing step, a state is maintained in which a first direction in the release surface of the wafer corresponding to a scanning direction of the laser beam and a second direction in the release surface of the ingot corresponding to the scanning direction of the laser beam or a second direction in the release surface of the other wafer corresponding to the scanning direction of the laser beam intersect each other, and the wafer and the ingot or the other wafer are moved relative to each other.

1. A processing method for a workpiece, the processing method comprising:
holding a first workpiece on a first holding portion and holding a second workpiece made of the same material as the first workpiece on a second holding portion; and
relatively moving the first workpiece and the second workpiece in an in-plane direction of a contact surface of the first workpiece and a contact surface of the second workpiece in a state in which the first workpiece and the second workpiece are in contact with each other to reduce unevenness of at least one of the contact surface of the first workpiece and the contact surface of the second workpiece,
wherein, in the moving, the first workpiece and the second workpiece are brought into contact with each other such that an extending direction of the unevenness present on the contact surface of the first workpiece and an extending direction of the unevenness present on the contact surface of the second workpiece intersect each other.

2. The processing method according to claim 1, further comprising
detecting, before or after the holding, the extending direction of the unevenness of the first workpiece and the extending direction of the unevenness of the second workpiece and adjusting a posture angle of at least one of the first workpiece and the second workpiece such that the extending direction of the unevenness of the first workpiece and the extending direction of the unevenness of the second workpiece intersect each other.

3. The processing method according to claim 2,
wherein, in the detecting, outer peripheral shapes of the first workpiece and the second workpiece are detected, and the extending direction of the unevenness of the first workpiece and the extending direction of the unevenness of the second workpiece are detected based on the outer peripheral shapes.

4. The processing method according to claim 2,
wherein, in the detecting, the contact surface of the first workpiece and the contact surface of the second workpiece are irradiated with light, reflected light reflected by the contact surface of the first workpiece and the contact surface of the second workpiece is detected, and the extending direction of the unevenness of the first workpiece and the extending direction of the unevenness of the second workpiece are detected based on the reflected light.

5. The processing method according to claim 1, further comprising:
before the holding,
forming a release layer in the ingot by positioning a focal point of a laser beam having a wavelength that is transmittable through the ingot inside the ingot and scanning the ingot with the laser beam;
producing a wafer by releasing the wafer from the ingot with the release layer as a starting point,
wherein the first workpiece is the ingot and the contact surface of the first workpiece is a release surface from which the wafer is released in the producing, or the first workpiece is the wafer and the contact surface of the first workpiece is a release surface released from the ingot in the producing,
wherein the second workpiece is the ingot and the contact surface of the second workpiece is a release surface from which the wafer is released in the producing, or the second workpiece is the wafer and the contact surface of the second workpiece is a release surface released from the ingot in the producing,
wherein the extending direction of the unevenness of the first workpiece and the extending direction of the unevenness of the second workpiece are scanning directions of the laser beam with respect to the first workpiece and the second workpiece in the forming, and
wherein, in the moving, a combination of the first workpiece and the second workpiece is any one of a combination of the ingot and the ingot, a combination of the wafer and the wafer, and a combination of the ingot and the wafer, and the first workpiece and the second workpiece are brought into contact with each other.

6. The processing method according to claim 1,
wherein, in the moving, the extending direction of the unevenness of the first workpiece and the extending direction of the unevenness of the second workpiece are fixed, and one of the first workpiece and the second workpiece is circumferentially moved relative to the other.

7. The processing method according to claim 1,
wherein, in the moving, the first workpiece and the second workpiece are rotated in the same direction and at the same speed in a state in which a center of the contact surface of the first workpiece is shifted with respect to a center of the contact surface of the second workpiece in the in-plane direction.

8. A processing device comprising:
a first holding portion configured to hold a first workpiece;
a second holding portion configured to hold a second workpiece made of the same material as the first workpiece held by the first holding portion so as to face the first workpiece held by the first holding portion; and
a moving mechanism configured to relatively move the first holding portion and the second holding portion in an in-plane direction of a contact surface of the first workpiece and a contact surface of the second workpiece in a state in which the first workpiece held by the first holding portion and the second workpiece held by the second holding portion are in contact with each other,
wherein the moving mechanism relatively moves the first holding portion and the second holding portion so as to maintain a state in which a first direction defined in the contact surface of the first workpiece held by the first holding portion and a second direction defined in the contact surface of the second workpiece held by the second holding portion intersect each other.

9. A wafer manufacturing method for manufacturing a wafer having a thickness less than a thickness of an ingot from the ingot, the wafer manufacturing method comprising:
forming a release layer inside the ingot by positioning a focal point of a laser beam having a wavelength that is transmittable through the ingot inside the ingot and scanning the ingot with the laser beam;
releasing the wafer from the ingot with the release layer as a starting point; and
reducing unevenness of a release surface of the wafer,
wherein, in the reducing, the wafer and the ingot or the other wafer are moved relative to each other in a state in which the release surface of the wafer is in contact with a release surface of the ingot or a release surface of the other wafer to which the reducing is not performed to reduce the unevenness of the release surface of the wafer, and
wherein, in the reducing, a state is maintained in which a first direction in the release surface of the wafer corresponding to a scanning direction of the laser beam and a second direction in the release surface of the ingot corresponding to the scanning direction of the laser beam or a second direction in the release surface of the other wafer corresponding to the scanning direction of the laser beam intersect each other, and the wafer and the ingot or the other wafer are moved relative to each other.
